(19) United States
(12) Patent Application Publication
(10) Pub. No.: US 2023/0402995 A1
(43) Pub. Date: Dec. 14, 2023

(54) Surface-Acoustic-Wave (SAW) Filter for Suppressing Intermodulation Distortion

(71) Applicant: RF360 EUROPE GMBH, Munich (DE)

(72) Inventors: Vikrant Chauhan, München (DE); Markus Mayer, Taufkirchen (DE); Werner Ruile, Munich (DE); Andreas Mayer, Freiburg im Breisgau (DE); Elena Mayer, Freiburg im Breisgau (DE)

(21) Appl. No.: 17/806,142

(22) Filed: Jun. 9, 2022

(51) Int. Cl. H03H 9/64; H03H 9/02; H03H 3/10

(52) U.S. Cl. CPC H03H 9/643; H03H 9/6489; H03H 9/02574; H03H 9/02559; H03H 3/10

(57) ABSTRACT

An apparatus is disclosed for a surface-acoustic-wave filter that suppresses intermodulation distortion. In an example aspect, the apparatus includes a surface-acoustic-wave filter including an electrode structure and at least one layer of quartz material with a thickness having a range approximately from 100 to 300 micrometers. The apparatus also includes at least one layer of lithium niobate (LiNbO3) material disposed between the electrode structure and the quartz material. A thickness of the lithium niobate material has a range approximately from 0.2 to 0.4 micrometers.

### TECHNICAL FIELD

This disclosure relates generally to wireless transceivers and other components that employ filters and, more specifically, to a surface-acoustic-wave (SAW) filter designed to suppress intermodulation distortion.

### BACKGROUND

Electronic devices use radio-frequency (RF) signals to communicate information. These radio-frequency signals enable users to talk with friends, download information, share pictures, remotely control household devices, and receive global positioning information. To transmit or receive the radio-frequency signals within a given frequency band, the electronic device may use filters to pass signals within the frequency band and to suppress (e.g., attenuate) jammers or noise having frequencies outside of the frequency band. As the number of available frequency bands increases and as the desired passband of filters widens, it can be challenging to design a filter that behaves linearly and suppresses intermodulation distortion.

### SUMMARY

An apparatus is disclosed that implements a surface-acoustic-wave (SAW) filter that suppresses intermodulation distortion. In example implementations, the surface-acoustic-wave filter includes at least one softening-spring layer and at least one hardening-spring layer. The thicknesses and/or crystal orientations of the softening-spring layer and the hardening-spring layer are tailored such that the surface-acoustic-wave filter behaves linearly, thereby suppressing intermodulation distortions. Additionally, the crystal orientations and thicknesses of the softening-spring layer and the hardening-spring layer can be further tailored to enable the surface-acoustic-wave filter to have an absolute value of a temperature coefficient of frequency (TCF) approximately equal to zero and to have a target electroacoustic coupling factor. By balancing the characteristics of the softening-spring layer and the hardening-spring layer, the surface-acoustic-wave filter can be implemented using a smaller footprint than other filter designs that rely on multiple cascading acoustic filters to attenuate at least a portion of an intermodulation distortion response of the surface-acoustic-wave filter.

In an example aspect, an apparatus is disclosed. The apparatus includes a surface-acoustic-wave filter with an electrode structure and at least one layer of quartz material with a thickness having a range approximately from 100 to 300 micrometers. The surface-acoustic-wave filter also includes at least one layer of lithium niobate (LiNbO3) material disposed between the electrode structure and the quartz material. A thickness of the lithium niobate material has a range approximately from 0.2 to 0.4 micrometers.

In an example aspect, an apparatus is disclosed. The apparatus includes a surface-acoustic-wave filter configured to generate a filtered signal from a radio-frequency signal. The surface-acoustic-wave filter includes means for converting the radio-frequency signal to an acoustic wave and converting a propagated acoustic wave into the filtered signal. The surface-acoustic-wave filter also includes softening means for propagating the acoustic wave across a planar surface to produce the propagated acoustic wave. The surface-acoustic-wave filter additionally includes hardening means for supporting the softening means. The softening means and the hardening means have respective thicknesses that enable the surface-acoustic-wave filter to behave substantially linearly.

In an example aspect, a method for manufacturing a surface-acoustic-wave filter that suppresses intermodulation distortion is disclosed. The method includes providing at least one layer of quartz material with a thickness having a range approximately from 100 to 300 micrometers. The method also includes providing at least one layer of lithium niobate (LiNbO3) material on a surface of the quartz material. A thickness of the lithium niobate material having a range approximately from 0.2 to 0.4 micrometers. The method additionally includes providing an electrode structure on a surface of the lithium niobate material.

In an example aspect, an apparatus is disclosed. The apparatus includes a surface-acoustic-wave filter with an electrode structure and at least one hardening-spring layer. The surface-acoustic-wave filter also includes at least one softening-spring layer disposed between the electrode structure and the hardening-spring layer.

In an example aspect, an apparatus is disclosed. The apparatus includes a surface-acoustic-wave filter with an electrode structure and at least one layer of quartz material. The surface-acoustic-wave filter also includes at least one layer of lithium niobate (LiNbO₃) material disposed between the electrode structure and the quartz material, the lithium niobate material having a planar surface and configured to enable propagation of an acoustic wave in a direction along a first filter (X) axis. A second filter (Y) axis is along the planar surface and perpendicular to the first filter (X) axis. A third filter (Z) axis is normal to the planar surface. An orientation of the first filter (X) axis, the second filter (Y) axis, and the third filter (Z) axis is relative to a crystalline structure of the lithium niobate material as defined by Euler angles lambda (λ), mu (μ), and theta (θ). A value of the Euler angle mu (μ) has a range approximately from −36° to 28° or at least one symmetrical equivalent thereof.

In an example aspect, an apparatus is disclosed. The apparatus includes a surface-acoustic-wave filter with an electrode structure and at least one layer of silicon dioxide material with a thickness having a range approximately from 350 to 550 nanometers. The surface-acoustic-wave filter also includes at least one layer of lithium tantalate (LiTaO3) material disposed between the electrode structure and the silicon dioxide material, a thickness of the lithium tantalate material having a range approximately from 400 to 600 nanometers.

In an example aspect, a method for manufacturing a surface-acoustic-wave filter that suppresses intermodulation distortion is disclosed. The method includes providing at least one layer of silicon dioxide material with a thickness having a range approximately from 350 to 550 nanometers. The method also includes providing at least one layer of lithium tantalate (LiTaO3) material on a surface of the silicon dioxide material. A thickness of the lithium tantalate material has a range approximately from 400 to 600 nanometers. The method additionally includes providing an electrode structure on a surface of the lithium tantalate material.

In an example aspect, an apparatus is disclosed. The apparatus includes a surface-acoustic-wave filter with an electrode structure and at least one layer of silicon dioxide material. The surface-acoustic-wave filter also includes at least one layer of lithium tantalate (LiTaO3) material disposed between the electrode structure and the silicon dioxide material, the lithium tantalate material having a planar surface and configured to enable propagation of an acoustic wave in a direction along a first filter (X) axis. A second filter (Y) axis is along the planar surface and perpendicular to the first filter (X) axis. A third filter (Z) axis is normal to the planar surface. An orientation of the first filter (X) axis, the second filter (Y) axis, and the third filter (Z) axis is relative to a crystalline structure of the lithium tantalate material as defined by Euler angles lambda (λ), mu (μ), and theta (θ). A value of the Euler angle mu (μ) has a range approximately from −70° to −30° or at least one symmetrical equivalent thereof.

### BRIEF DESCRIPTION OF DRAWINGS

FIG. 1 illustrates an example operating environment for a surface-acoustic-wave filter that suppresses intermodulation distortion.

FIG. 2 illustrates an example wireless transceiver including at least one wideband filter.

FIG. 3 illustrates example components of a surface-acoustic-wave filter that suppresses intermodulation distortion.

FIG. 4 illustrates example Euler angles that define an orientation of a softening-spring layer or a hardening-spring layer of a surface-acoustic-wave filter that suppresses intermodulation distortion.

FIG. 5 illustrates an example implementation of a surface-acoustic-wave filter that suppresses intermodulation distortion.

FIG. 6-1 illustrates an example implementation of a high-quality temperature-compensated surface-acoustic-wave filter that suppresses intermodulation distortion.

FIG. 6-2 depicts graphs that illustrate various example performance characteristics of some described surface-acoustic-wave filters that suppress intermodulation distortion.

FIG. 7 illustrates an example implementation of a thin-film surface-acoustic-wave filter that suppresses intermodulation distortion.

FIG. 8 is a flow diagram illustrating an example process for manufacturing a surface-acoustic-wave filter that suppresses intermodulation distortion.

FIG. 9 is a flow diagram illustrating another example process for manufacturing a surface-acoustic-wave filter that suppresses intermodulation distortion.

### DETAILED DESCRIPTION

To transmit or receive radio-frequency signals within a given frequency band, an electronic device may use filters to pass signals within the frequency band and to suppress (e.g., attenuate) jammers or noise having spurious frequencies outside of the frequency band. As the number of available frequency bands increases and as the desired passbands of filters widen, it can be challenging to design a filter that behaves linearly and suppresses intermodulation distortion.

Electroacoustic devices (e.g., “acoustic filters”) can be used to filter high-frequency (e.g., generally greater than 100 MHz) signals in many applications. An acoustic filter is tuned to pass certain frequencies (e.g., frequencies within its passband) and attenuate other frequencies (e.g., frequencies that are outside of its passband). Using a piezoelectric material as a vibrating medium, the acoustic filter operates by transforming an electrical signal wave that is propagating along an electrical conductor into an acoustic wave (e.g., an acoustic signal wave) that forms across the piezoelectric material. The acoustic wave is then converted back into an electrical filtered signal.

The acoustic wave propagates across the piezoelectric material at a velocity having a magnitude that is significantly less than that of the propagation velocity of the electrical wave. Generally, the magnitude of the propagation velocity of a wave is proportional to a size of a wavelength of the wave. Consequently, after conversion of the electrical signal wave into the acoustic signal wave, the wavelength of the acoustic signal wave is significantly smaller than the wavelength of the electrical signal wave. The resulting smaller wavelength of the acoustic signal wave enables filtering to be performed using a smaller filter device. This permits acoustic filters to be used in space-constrained devices, including portable electronic devices such as cellular phones.

Some filter designs can suppress intermodulation distortion at the cost of introducing additional cascading acoustic filters, which occupy additional space within the device. Still other filter designs cannot achieve a target linearity without increasing an absolute value of a temperature coefficient of frequency.

Without sufficient linearity, the resulting intermodulation distortion can deteriorate wireless communication performance. For example, an acoustic filter can filter a radio-frequency signal for transmission. In the process of filtering this signal for transmission, the non-linear behavior of the acoustic filter can generate an undesired signal having a spurious or undesired frequency (e.g., a harmonic frequency of the radio-frequency signal, a frequency representing a summation of two or more frequencies within the radio-frequency signal, or a frequency representing a subtraction of two or more frequencies within the radio-frequency signal). In some situations, this undesired signal from transmission operations can leak into a receive path and make it challenging to receive a desired signal.

To address these challenges, techniques for implementing a surface-acoustic-wave (SAW) filter that suppresses intermodulation distortion is described. In example implementations, the surface-acoustic-wave filter includes at least one softening-spring layer and at least one hardening-spring layer. In some cases, the softening-spring layer can be implemented using lithium niobate material, lithium tantalate material, or a combination thereof. The hardening-spring layer can be implemented using a quartz material, a silicon dioxide material, or a combination thereof.

The thicknesses and/or crystal orientations of the softening-spring layer and the hardening-spring layer are tailored such that the surface-acoustic-wave filter behaves linearly, thereby suppressing intermodulation distortions. Additionally, the crystal orientations and thicknesses of the softening-spring layer and the hardening-spring layer can be further tailored to enable the surface-acoustic-wave filter to have an absolute value of the temperature coefficient of frequency approximately equal to zero and to have a target electroacoustic coupling factor. By balancing the characteristics of the softening-spring layer and the hardening-spring layer, the surface-acoustic-wave filter can be implemented using a smaller footprint than other filter designs that rely on multiple cascading acoustic filters to attenuate at least a portion of an intermodulation distortion response of the surface-acoustic-wave filter.

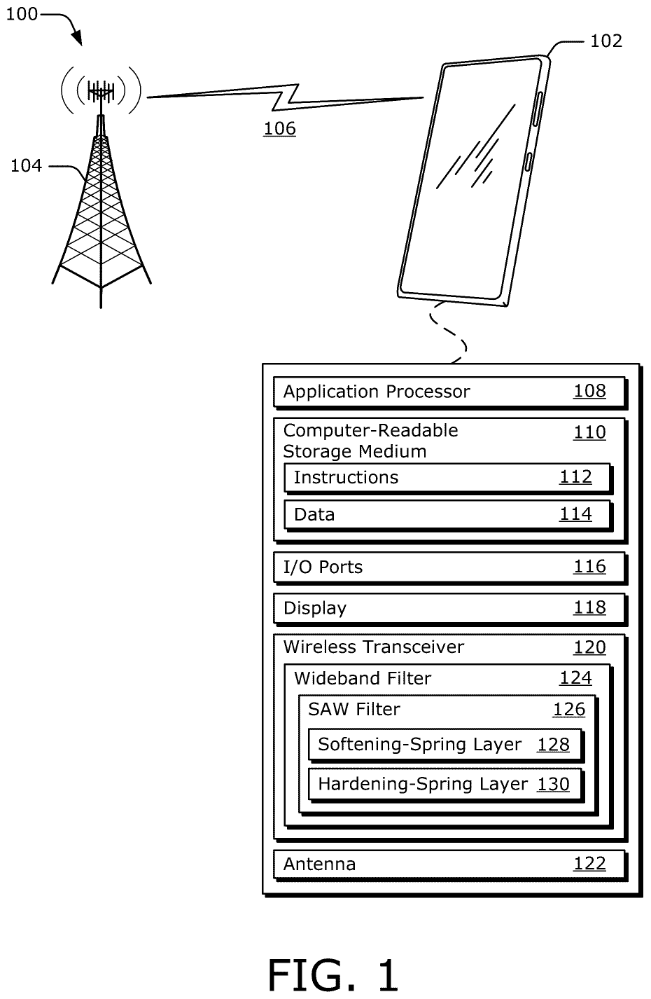

FIG. 1 illustrates an example environment 100 for operating a surface-acoustic-wave filter that suppresses intermodulation distortion. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, a fiber optic line, and so forth. Therefore, the computing device 102 may communicate with the base station 104 or another device via a wired connection, a wireless connection, or a combination thereof.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), or 5th-generation (5G) cellular; IEEE 802.11 (e.g., Wi-Fi™); IEEE 802.15 (e.g., Bluetooth™); IEEE 802.16 (e.g., WiMAX™); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. Alternatively or additionally, the computing device 102 can include a wired transceiver, such as an Ethernet or fiber optic interface for communicating over a local network, intranet, or the Internet. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

In the example shown in FIG. 1, the wireless transceiver 120 includes at least one wideband filter 124. The wideband filter 124 can have a relative bandwidth of approximately 10% or more of a main-resonance frequency (e.g., a relative bandwidth approximately equal to 10%, 12%, 20%, 24%, or 26% of the main-resonance frequency). The wideband filter 124 is implemented using at least one surface-acoustic-wave filter 126 (SAW Filter 126). The surface-acoustic-wave filter 126 can be implemented as a thin-film (TF) surface-acoustic-wave filter (TF SAW filter) or a high-quality temperature-compensated (HQ-TC) surface-acoustic-wave filter (HQ-TC SAW filter). In some implementations, the wideband filter 124 can include multiple surface-acoustic-wave filters 126 arranged in series, in parallel, in a ladder structure, in a lattice structure, or some combination thereof. Although performance characteristics of the surface-acoustic-wave filter 126 can be particularly advantageous for implementing the wideband filter 124, the techniques described herein can also be used to implement other types of acoustic filters with narrower bandwidths, and the surface-acoustic-wave filter 126 can be used in other components of the computing device 102 besides the wireless transceiver 120.

In example implementations, the surface-acoustic-wave filter 126 includes at least one softening-spring layer 128 and at least one hardening-spring layer 130. The softening-spring layer 128 exhibits characteristics of spring softening such that a slope of a stress-strain curve behaves non-linearly and decreases for increasing strain. In contrast, the hardening-spring layer 130 exhibits characteristics of spring hardening such that the slope of the stress-strain curve behaves non-linearly and increases for increasing strain. In general, it is difficult to maintain equilibrium with the softening-spring layer 128, which has “too little” restoring force, or the hardening-spring layer 130, which has “too much” restoring force. Some surface-acoustic-wave filters implemented with either one or both of the softening-spring layer 128 and the hardening-spring layer 130 can exhibit this non-linear behavior and therefore introduce intermodulation distortion.

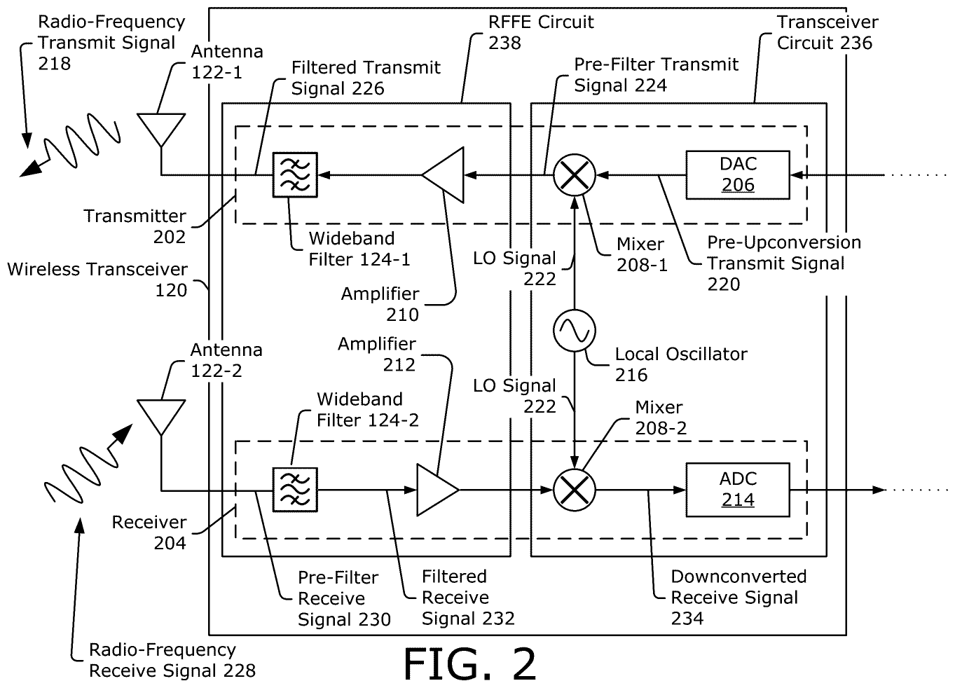

Instead, to implement a surface-acoustic-wave filter 126 as described herein, the thicknesses of the softening-spring layer 128 and the hardening-spring layer 130 are tailored such that the combined stress-strain curve behaves linearly. This enables the surface-acoustic-wave filter 126 to realize a linear stress-strain curve. By enabling the surface-acoustic-wave filter 126 to exhibit linear behavior, the generation of intermodulation distortion is suppressed (e.g., attenuated or reduced). Example intermodulation distortions can include intermodulation distortions of the second order, the third order, the fourth order, and so forth. The wideband filter 124 is further described with respect to FIG. 2.

FIG. 2 illustrates an example wireless transceiver 120 with at least one wideband filter 124. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be selectively connected to a same antenna through a switch (not shown). The transmitter 202 is shown to include at least one digital-to-analog converter 206 (DAC 206), at least one first mixer 208-1, at least one amplifier 210 (e.g., a power amplifier), and at least one first wideband filter 124-1. The receiver 204 includes at least one second wideband filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the digital-to-analog converter 206 of the transmitter 202 and the analog-to-digital converter 214 of the receiver 204 can be coupled to the application processor 108 (of FIG. 1) or another processor associated with the wireless transceiver 120 (e.g., a modem).

In some implementations, the wireless transceiver 120 is implemented using multiple circuits, such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the digital-to-analog converter 206 of the transmitter 202, the mixer 208-1 of the transmitter 202, the mixer 208-2 of the receiver 204, and the analog-to-digital converter 214 of the receiver 204. In other implementations, the digital-to-analog converter 206 and the analog-to-digital converter 214 can be implemented on another separate circuit that includes the application processor 108 or the modem. The radio-frequency front-end circuit 238 includes the amplifier 210 of the transmitter 202, the wideband filter 124-1 of the transmitter 202, the wideband filter 124-2 of the receiver 204, and the amplifier 212 of the receiver 204.

During transmission, the transmitter 202 generates a radio-frequency transmit signal 218 (e.g., a wireless signal or a wireless communication signal), which is transmitted using the antenna 122-1. To generate the radio-frequency transmit signal 218, the digital-to-analog converter 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an unconverted signal, which is referred to as a pre-filter transmit signal 224. The pre-filter transmit signal 224 can be a radio-frequency signal and include some spurious (e.g., unwanted) frequencies, such as a harmonic frequency or an intermodulation distortion product. The amplifier 210 amplifiers the pre-filter transmit signal 224 and passes the amplified pre-filter transmit signal 224 to the wideband filter 124-1. The first wideband filter 124-1 filters the amplified pre-filter transmit signal 224 to generate a filtered transmit signal 226. As part of the filtering process, the first wideband filter 124-1 attenuates the one or more spurious frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second wideband filter 124-2 accepts the received radio-frequency receive signal 228, which is represented by a pre-filter receive signal 230. The second wideband filter 124-2 filters any spurious frequencies within the pre-filter receive signal 230 to generate a filtered receive signal 232. Example spurious frequencies can include jammers or noise from the external environment. The amplifier 212 of the receiver 204 amplifies the filtered receive signal 232 and passes the amplified filtered receive signal 232 to the second mixer 208-2. The second mixer 208-2 downconverts the amplified filtered receive signal 232 using the local oscillator signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem).

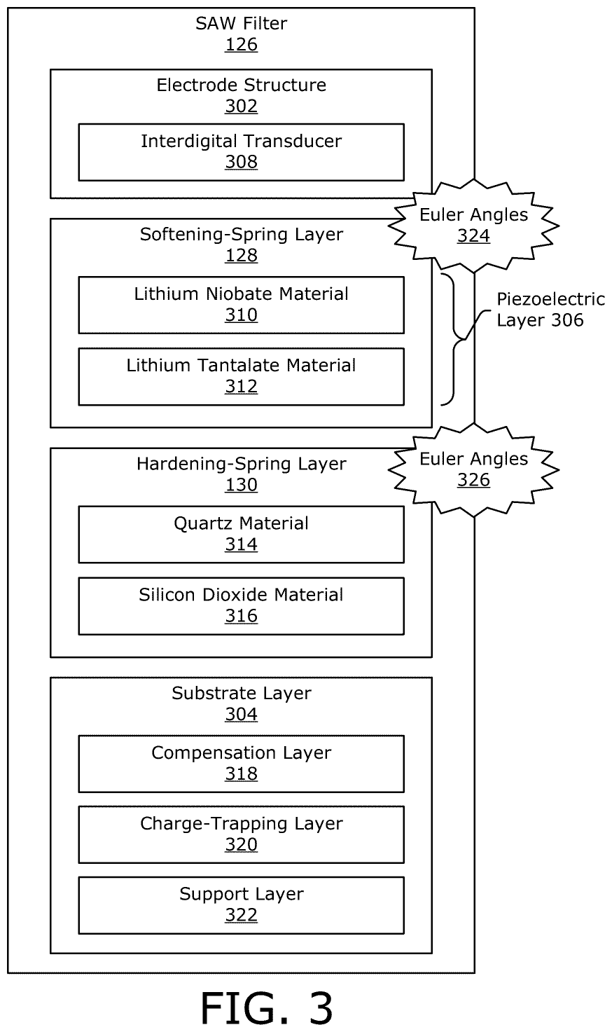

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which the wideband filters 124 may be included. For example, the wideband filters 124 can be integrated within duplexers or diplexers of the wireless transceiver 120. The wideband filters 124-1 and 124-2 can be implemented by one or more surface-acoustic-wave filters 126, an example of which is further described with respect to FIG. 3.

FIG. 3 illustrates example components of the surface-acoustic-wave filter 126. In the depicted configuration, the surface-acoustic-wave filter 126 includes at least one electrode structure 302, the softening-spring layer 128, the hardening-spring layer 130, and at least one substrate layer 304. The softening-spring layer 128 forms at least one piezoelectric layer 306.

The electrode structure 302 comprises a conductive material, such as metal, and can include one or more layers. The one or more layers can include one or more metal layers and can optionally include one or more adhesion layers. As an example, the metal layers can be composed of aluminium (Al), copper (Cu), silver (Ag), gold (Au), tungsten (W), or some combination or doped version thereof. The adhesion layers can be composed of chromium (Cr), titanium (Ti), molybdenum (Mo), or some combination thereof.

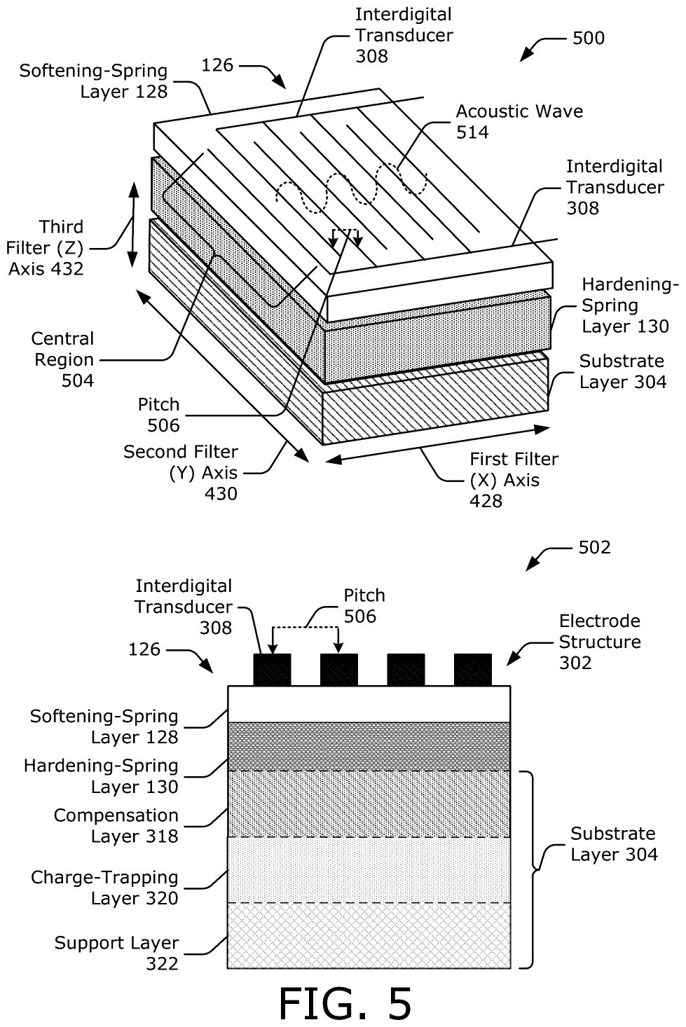

The electrode structure 302 can include one or more interdigital transducers 308. The interdigital transducer 308 converts an electrical signal into an acoustic wave and converts the acoustic wave into a filtered electrical signal. An example interdigital transducer 308 is further described with respect to FIG. 5. Although not explicitly shown, the electrode structure 302 can also include two or more reflectors. In an example implementation, the interdigital transducer 308 is arranged between two reflectors, which reflect the acoustic wave back towards the interdigital transducer 308.

In example implementations, the softening-spring layer 128 is formed using lithium niobate (LiNbO₃) material 310, lithium tantalate (LiTaO₃) material 312, or some combination thereof. The lithium niobate material 310 can alternatively be referred to as a lithium niobate layer, a lithium niobate plate, a lithium niobate film, or a lithium niobate substrate. Lithium niobate is a type of crystal composed of niobium, lithium, and oxygen. The lithium niobate material 310 can be composed of this lithium niobate crystal, or a similar type of crystal, such as doped lithium niobate. Other types of mixed crystals that have a similar symmetry as lithium niobate can also be used to form the lithium niobate material 310.

The lithium tantalate material 312 can alternatively be referred to as a lithium tantalate layer, a lithium tantalate plate, a lithium tantalate film, or a lithium tantalate substrate. Lithium tantalate is a type of crystal composed of tantalum, lithium, and oxygen. The lithium tantalate material 312 can be composed of this lithium tantalate crystal, or a similar type of crystal, such as doped lithium tantalate. Other types of mixed crystals that have a similar symmetry as lithium tantalate can also be used to form the lithium tantalate material 312.

The softening-spring layer 128 forms the piezoelectric material for the surface-acoustic-wave filter 126. The material of the piezoelectric layer 306 and the orientation of the propagation surface with respect to the crystal structure of the material affects several performance parameters. Example performance parameters include an electroacoustic coupling factor (K²), a temperature coefficient of frequency (TCF), a mode or type of acoustic wave produced, and/or a velocity of the acoustic wave. The electroacoustic coupling factor characterizes an efficiency of the surface-acoustic-wave filter 126 in converting between electrical energy and mechanical energy. A filter with a higher electroacoustic coupling factor experiences less insertion loss over a wider frequency range and improved impedance matching than another filter with a lower electroacoustic coupling factor. The temperature coefficient of frequency characterizes an amount a resonant frequency or filter skirt of the filter changes in response to a change in temperature. A filter with a smaller absolute value of the temperature coefficient of frequency has a more stable frequency response over a range of temperatures compared to another filter with a larger absolute value of the temperature coefficient of frequency.

The hardening-spring layer 130 is formed using quartz material 314, silicon dioxide (SiO₂) material 316, or some combination thereof. In some implementations, the hardening-spring layer 130 can include the substrate layer 304. The softening-spring layer 128 and the hardening-spring layer 130 have particular crystal orientations and/or thicknesses for suppressing intermodulation distortion. The thicknesses of the softening-spring layer 128 and the hardening-spring layer 130 can also be chosen to enable the surface-acoustic-wave filter 126 to realize a combined absolute value of the temperature coefficient of frequency that is approximately equal to zero (e.g., less than 5 parts-per-million per degree Celsius or less than 2 parts-per-million per degree Celsius). In some implementations, the softening-spring layer 128 has a negative temperature coefficient of frequency and the hardening-spring layer 130 has a positive temperature coefficient of frequency.

The substrate layer 304 includes one or more sublayers that can support passivation, temperature compensation, power handling, mode suppression, and so forth. As an example, the substrate layer 304 can include at least one compensation layer 318, at least one charge-trapping layer 320, at least one support layer 322, or some combination thereof. These sublayers can be considered part of the substrate layer 304 or their own separate layers.

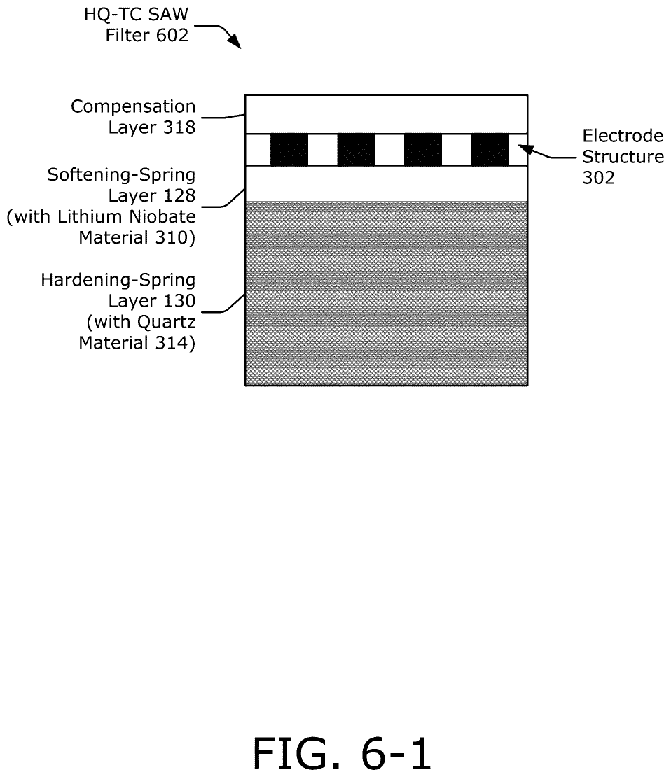

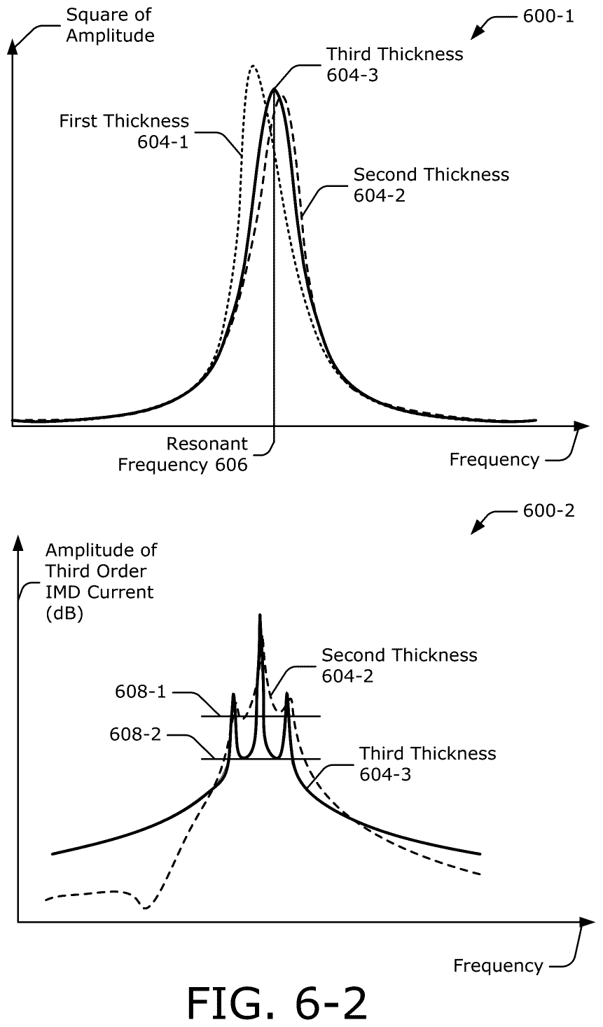

The compensation layer 318 can provide temperature compensation to enable the surface-acoustic-wave filter 126 to achieve the target temperature coefficient of frequency based on the thickness of the softening-spring layer 128. In example implementations, the compensation layer 318 can be implemented using at least one silicon dioxide layer. In some applications, the substrate layer 304 may not include, for instance, the compensation layer 318 to reduce the cost of the surface-acoustic-wave filter 126. Some implementations can additionally or alternatively include the compensation layer 318 on top of the electrode structure 302. In this case, the electrode structure 302 is disposed between the compensation layer 318 and the softening-spring layer 128 (as shown in FIG. 6-1).

The charge-trapping layer 320 can suppress nonlinear substrate effects. The charge-trapping layer 320 can include at least one polysilicon (poly-Si) layer (e.g., a polycrystalline silicon layer or a multicrystalline silicon layer), at least one amorphous silicon layer, at least one silicon nitride (SiN) layer, at least one silicon oxynitride (SiON) layer, at least one aluminium nitride (AlN) layer, or some combination thereof.

The support layer 322 can enable the acoustic wave to form across the surface of the piezoelectric layer 306 and reduce the amount of energy that leaks into the substrate layer 304. In some implementations, the support layer 322 can also act as a compensation layer 318. In general, the support layer 322 is composed of material that is non-conducting and provides isolation. For example, the support layer 322 can include at least one silicon (Si) layer (e.g., a doped high-resistive silicon layer), at least one sapphire layer, at least one silicon carbide (SiC) layer, at least one fused silica layer, at least one glass layer, at least one diamond layer, or some combination thereof.

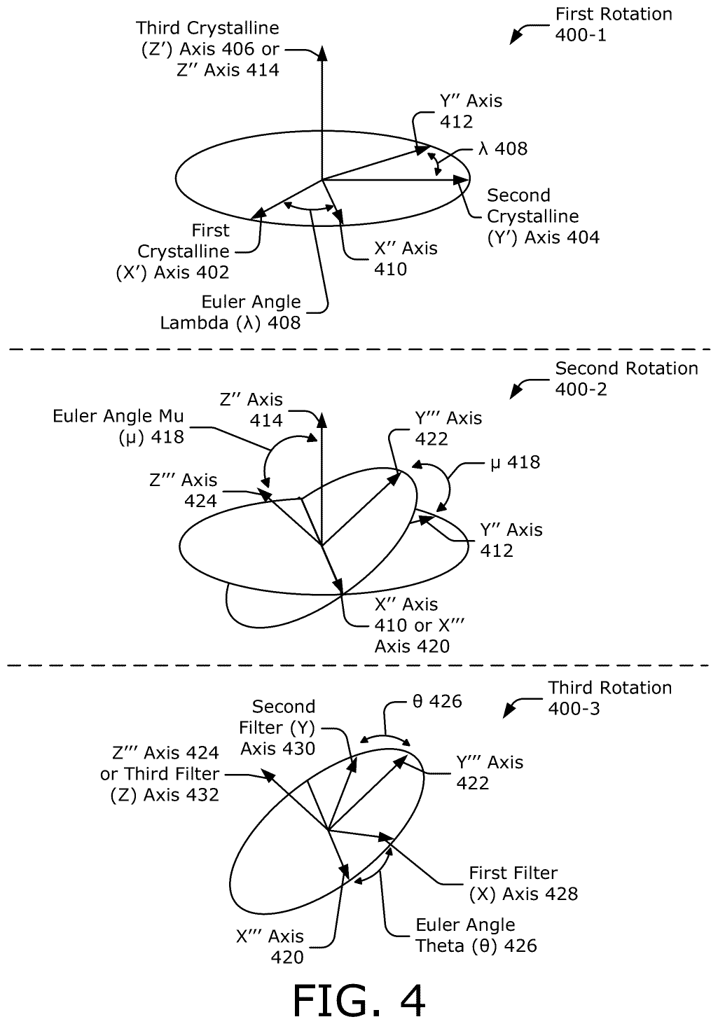

To achieve a target performance level, the softening-spring layer 128 and the hardening-spring layer 130 are implemented with respective Euler angles 324 and 326, which are further described with respect to FIG. 4. The Euler angles 324 and 326 can be tailored to realize a target electroacoustic coupling factor. The thicknesses of the softening-spring layer 128 and the hardening-spring layer 130 can also be tailored to achieve the target electroacoustic coupling factor, a target temperature coefficient of frequency, and the linear filtering behavior.

FIG. 4 illustrates example Euler angles 324 or 326 (of FIG. 3) that define respective orientations of the softening-spring layer 128 and the hardening-spring layer 130 of the surface-acoustic-wave filter 126 relative to a crystalline structure of the material. Each set of Euler angles 324 or 326 includes three Euler angles: lambda (λ), mu (μ), and theta (θ), which are further defined below.

In FIG. 4, a first crystalline (X′) axis 402, a second crystalline (Y′) axis 404, and a third crystalline (Z′) axis 406 are fixed along crystallographic axes of the material. A first rotation 400-1 is applied to rotate the first crystalline X′ axis 402 and the second crystalline Y′ axis 404 about the third crystalline Z′ axis 406. In particular, the first rotation 400-1 rotates the first crystalline X′ axis 402 in a direction of the second crystalline Y′ axis 404. The angle associated with the first rotation 400-1 characterizes one of the Euler angles, which is represented by Euler angle lambda (λ) 408. The resulting rotated axes are represented by a new set of axes: an X″ axis 410, a Y″ axis 412, and a Z″ axis 414. As shown in FIG. 4, the third crystalline Z′ axis 406 remains unchanged by the first rotation 400-1 such that the third crystalline Z′ axis 406 is equal to the Z″ axis 414.

In a second rotation 400-2, the Y″ axis 412 and the Z″ axis 414 are rotated about the X″ axis 410 by another Euler angle, which is represented by Euler angle mu (μ) 418. In this case, the Y″ axis 412 is rotated in the direction of the Z″ axis 414. The resulting rotated axes are represented by a new set of axes: an X′″ axis 420, a Y′″ axis 422, and a Z′″ axis 424. As shown in FIG. 4, the X″ axis 410 remains unchanged by the second rotation 400-2 such that the X″ axis 410 is equal to the X′″ axis 420.

In a third rotation 400-3, the X′″ axis 420 and the Y′″ 422 axis are rotated about the Z′″ axis 424 by an additional Euler angle, which is represented by Euler angle theta (θ) 426. In this case, the X′″ axis 420 is rotated in the direction of the Y′″ axis 422. The resulting rotated axes are represented by a first filter X axis 428, a second filter Y axis 430, and a third filter Z axis 432. As shown in FIG. 4, the Z′″ axis 424 remains unchanged by the third rotation 400-3 such that the Z′″ axis 424 is equal to the third filter Z axis 432. The first filter X axis 428 specifies the direction of formation of an acoustic wave, as further described with respect to FIG. 5.

FIG. 5 illustrates an example implementation of the surface-acoustic-wave filter 126 using the softening-spring layer 128 and the hardening-spring layer 130. A three-dimensional perspective view 500 of the surface-acoustic-wave filter 126 is shown at the top of FIG. 5, and a two-dimensional cross-section view 502 of the surface-acoustic-wave filter 126 is shown at the bottom of FIG. 5.

In the depicted configuration shown in the two-dimensional cross-section view 502, the softening-spring layer 128 is disposed between the electrode structure 302 and the hardening-spring layer 130. In some implementations, the hardening-spring layer 130 acts as the substrate layer 304. In other implementations, the surface-acoustic-wave filter 126 includes one or more substrate layers 304 in addition to the hardening-spring layer 130. In this case, the hardening-spring layer 130 is disposed between the softening-spring layer 128 and the substrate layer 304.

The substrate layer 304 can include the compensation layer 318, the charge-trapping layer 320, and/or the support layer 322. In the illustrated example, the compensation layer 318 is disposed between the hardening-spring layer 130 and the charge-trapping layer 320. The charge-trapping layer 320 is disposed between the compensation layer 318 and the support layer 322. The electrode structure 302 includes the interdigital transducer 308. Although not explicitly shown in FIG. 5, the electrode structure 302 can also include one or more other interdigital transducers 308 and two or more reflectors.

In the three-dimensional perspective view 500, the interdigital transducer 308 is shown to have two comb-shaped electrode structures with fingers extending towards each other from two busbars (e.g., conductive segments or rails). The electrode fingers are arranged in an interlocking manner in between the two busbars of the interdigital transducer 308 (e.g., arranged in an interdigitated manner). In other words, the fingers connected to a first busbar extend towards a second busbar but do not connect to the second busbar. As such, there is a gap between the ends of these fingers and the second busbar. Likewise, fingers connected to the second busbar extend towards the first busbar but do not connect to the first busbar. There is therefore a gap between the ends of these fingers and the first busbar.

In the direction along the fingers, there is an overlap region including a central region 504 where a portion of one finger overlaps with a portion of an adjacent finger. This central region 504, including the overlap, may be referred to as the aperture, track, or active region where electric fields are produced between fingers to cause an acoustic wave 514 to form at least in this region of the softening-spring layer 128.

A physical periodicity of a spacing between adjacent ones of the fingers is referred to as a pitch 506 of the interdigital transducer 308. The pitch 506 may be indicated in various ways. For example, in certain aspects, the pitch 506 may correspond to a magnitude of a distance between consecutive fingers of the interdigital transducer 308 in the central region 504. This distance may be defined, for example, as the distance between center points of each of the fingers. The distance may be generally measured between a right (or left) edge of one finger and the right (or left) edge of an adjacent finger when the fingers have uniform widths. In certain aspects, an average of distances between adjacent fingers of the interdigital transducer 308 may be used for the pitch 506.

The frequency at which the softening-spring layer 128 vibrates is referred to as a main-resonance frequency of the electrode structure 302. The frequency is determined at least in part by the pitch 506 of the interdigital transducer 308 and other properties of the surface-acoustic-wave filter 126.

It should be appreciated that while a certain number of fingers are illustrated in FIG. 5, the number of fingers and the lengths and width of the fingers and busbars may be different in an actual implementation. Such parameters can depend on the particular application and desired filter characteristics. In addition, the surface-acoustic-wave filter 126 can include multiple interconnected electrode structures 302, with each including multiple interdigital transducers 308 to achieve a desired passband (e.g., can include multiple interconnected resonators or interdigital transducers 308 in series or parallel connections to form a desired filter transfer function).

Although not shown, each reflector within the electrode structure 302 can have two busbars and a grating structure of conductive fingers that each connect to both busbars. In some implementations, a pitch of the reflector can be similar to or the same as the pitch 506 of the interdigital transducer 308 to reflect the acoustic wave 514 in the resonant frequency range.

In the three-dimensional perspective view 500, the surface-acoustic-wave filter 126 is defined by a first filter (X) axis 428, a second filter (Y) axis 430, and a third filter (Z) axis 432. The first filter axis 428 and the second filter axis 430 are parallel to planar surfaces of the softening-spring layer 128 and the hardening-spring layer 130. The second filter axis 430 is perpendicular to the first filter axis 428. The third filter axis 432 is normal (e.g., perpendicular) to the planar surfaces of the softening-spring layer 128 and the hardening-spring layer 130. The busbars of the interdigital transducer 308 are oriented to be parallel to the first filter axis 428. Also, an orientation of the softening-spring layer 128 causes an acoustic wave 514 to mainly form in a direction of the first filter axis 428. As such, the acoustic wave 514 forms so as to have a direction of propagation that is substantially perpendicular to the direction of the fingers and substantially parallel to the busbars of the interdigital transducer 308.

During operation, the surface-acoustic-wave filter 126 accepts a radio-frequency signal, such as the pre-filter transmit signal 224 or the pre-filter receive signal 230 shown in FIG. 2. The electrode structure 302 excites an acoustic wave 514 on the softening-spring layer 128 using the inverse piezoelectric effect. For example, the interdigital transducer 308 in the electrode structure 302 generates an alternating electric field based on the accepted radio-frequency signal. The softening-spring layer 128 enables the acoustic wave 514 to be formed in response to the alternating electric field generated by the interdigital transducer 308. In other words, the softening-spring layer 128 causes, at least partially, the acoustic wave 514 to form responsive to electrical stimulation by one or more interdigital transducers 308.

The acoustic wave 514 propagates across the softening-spring layer 128 and interacts with the interdigital transducer 308 or another interdigital transducer within the electrode structure 302 (not shown in FIG. 5). In some implementations, two reflectors within the electrode structure 302 cause the acoustic wave 514 to be formed as a standing wave across a portion of the softening-spring layer 128. In other implementations, the acoustic wave 514 propagates across the softening-spring layer 128 from the interdigital transducer 308 to another interdigital transducer.

Using the piezoelectric effect, the electrode structure 302 generates a filtered radio-frequency signal based on the propagated surface acoustic wave 514. In particular, the softening-spring layer 128 generates an alternating electric field due to the mechanical stress generated by the propagation of the acoustic wave 514. The alternating electric field induces an alternating current in the other interdigital transducer or the interdigital transducer 308. This alternating current forms the filtered radio-frequency signal, which is provided at an output of the surface-acoustic-wave filter 126. The filtered radio-frequency signal can include the filtered transmit signal 226 or the filtered receive signal 232 of FIG. 2. Example implementations of the surface-acoustic-wave filter 126 are further described with respect to FIGS. 6-1 and 7.

FIG. 6-1 illustrates an example surface-acoustic-wave filter 126 that suppresses intermodulation distortion. In this example, the surface-acoustic-wave filter 126 is implemented as a high-quality temperature-compensated surface-acoustic-wave filter 602 (HQ-TC SAW filter 602). In the depicted configuration, the high-quality temperature-compensated surface-acoustic-wave filter 602 includes the compensation layer 318, the electrode structure 302, the softening-spring layer 128, and the hardening-spring layer 130. In this implementation, electrode structure 302 is disposed between the compensation layer 318 and the softening-spring layer 128. The compensation layer 318 can be implemented using silicon dioxide (SiO₂) material. The hardening-spring layer 130 forms the substrate layer 304 (e.g., of FIGS. 3 and 5). The softening-spring layer 128 is implemented using the lithium niobate material 310. The hardening-spring layer 130 is implemented using the quartz material 314. Alternatively, in other implementations not shown, the hardening-spring layer 130 can be implemented using the silicon dioxide material 316.

As shown in FIG. 6-1 (but not necessarily to scale), a thickness of the hardening-spring layer 130 is significantly larger than a thickness of the softening-spring layer 128 (e.g., 500 times larger or more). As an example, the thickness of the hardening-spring layer 130 can be approximately between 100 and 300 micrometers (μm), and the thickness of the softening-spring layer 128 can be approximately between 0.2 and 0.4 μm. In an example implementation, the hardening-spring layer 130 has a thickness of approximately 150 μm, and the softening-spring layer 128 has a thickness of approximately 0.28 μm. In general, the term “approximately” can mean that any of the thicknesses can be within +/−10% of a specified value or less (e.g., within +/−5%, +/−3% or +/−2% of a specified value).

An orientation of the first filter X axis 408, the second filter Y axis 410, and the third filter Z axis 412 (each of FIG. 4) relative to a crystalline structure of the lithium niobate material 310 of the softening-spring layer 128 is defined by the Euler angles lambda (λ) 408, mu (μ) 418, and theta (θ) 426. In particular, the lithium niobate material 310 can have a crystal orientation such that a value of the Euler angle mu (μ) 418 is approximately between −36° and 28°. In example implementations, the Euler angle mu (μ) 418 can be approximately 28°. Alternatively, the lithium niobate material 310 can have an equivalent crystal orientation due to crystal symmetry. In these examples, a symmetrically equivalent crystal orientation results in an Euler angle mu (μ) 418 that is approximately between 144° and 208° due to crystal symmetry. The crystal symmetry enables the lithium niobate material 310 to have similar properties between two angles of mu (μ) 418, which are separated by 180° by, for instance, flipping the material over on the hardening-spring layer 130. A value of the Euler angles lambda (λ) 408 and theta (θ) 426 can each be approximately between −10° and +10°, approximately between −5° and +5°, or approximately equal to 0°.

An orientation of the first filter X axis 408, the second filter Y axis 410, and the third filter Z axis 412 relative to a crystalline structure of the quartz material 314 of the hardening-spring layer 130 is also defined by the Euler angles lambda (λ) 408, mu (μ) 418, and theta (θ) 426. In particular, the quartz material 314 can have a crystal orientation such that a value of the Euler angle mu (μ) 418 is approximately between −45° and −58°. In example implementations, the Euler angle mu (μ) 418 can be approximately equal to −56°. Alternatively, the quartz material 314 can have an equivalent crystal orientation due to crystal symmetry. In these examples, a symmetrically equivalent crystal orientation results in an Euler angle mu (μ) 418 that is approximately between 122° and 135° due to crystal symmetry. The crystal symmetry enables the quartz material 314 to have similar properties between two angles of mu (μ) 418, which are separated by 180° by, for instance, flipping the material over. A value of the Euler angles lambda (λ) 408 and theta (θ) 426 can each be approximately between −10° and +10°, approximately between −5° and +5°, or approximately equal to 0°.

In general, a variation in any of the Euler angles 324 or 326 can be less than or equal to +/−1.5° due to measuring accuracy. Sometimes the variation in any of the Euler angles 324 or 326 is less than or equal to +/−0.2°. Therefore, the term approximately can mean that any of the Euler angles can be within +/−1.5° of a specified value or less (e.g., within +/−0.2° of a specified value). With the softening-spring layer 128 and the hardening-spring layer 130, the high-quality temperature-compensated surface-acoustic-wave filter 602 can suppress intermodulation distortion, as further described with respect to FIG. 6-2.

FIG. 6-2 depicts example graphs 600-1 and 600-2, which illustrate various example performance characteristics of some described surface-acoustic-wave filters 126. A first graph 600-1 depicts a relationship between the thickness of the softening-spring layer 128 and a resonance curve of the high-quality temperature-compensated surface-acoustic-wave filter 602 of FIG. 6-1. As shown in the graph 600-1, different thicknesses of the softening-spring layer 128 (e.g., thicknesses 604-1, 604-2, and 604-3) result in the resonance curve being bent to the left, bent to the right, or centered on a resonant frequency 606. In general, the thicknesses of the softening-spring layer 128 and the hardening-spring layer 130 are optimized, or at least tuned, to enable the surface-acoustic-wave filter 126 to behave substantially linearly and to suppress intermodulation distortion.

In a first example, the softening-spring layer 128 has the first thickness 604-1, such as approximately 0.25 μm. In this case, the first thickness 604-1 causes the surface-acoustic-wave filter 126 to behave non-linearly and exhibit characteristics of spring hardening. In other words, the first thickness 604-1 is not sufficient (e.g., is too small) to enable the softening-spring layer 128 to compensate for the properties of the hardening-spring layer 130. As such, the behavior of the hardening-spring layer 130 dominates (e.g., determines or more strongly influences) the behavior of the surface-acoustic-wave filter 126.

In a second example, the softening-spring layer 128 has the second thickness 604-2, such as approximately. 0.35 μm. In this case, the second thickness 604-2 causes the surface-acoustic-wave filter 126 to behave non-linearly and exhibit characteristics of spring softening. In other words, the second thickness 604-2 overcompensates for the properties of the hardening-spring layer 130. Consequently, the behavior of the softening-spring layer 128 dominates the behavior of the surface-acoustic-wave filter 126.

In a third example, the softening-spring layer 128 has the third thickness 604-3, such as approximately 0.28 μm. In this case, the third thickness 604-3 is sufficient to compensate for the characteristics of the hardening-spring layer 130 without dominating the hardening-spring layer 130. As such, the non-linear characteristics of the softening-spring layer 128 and the hardening-spring layer 130 neutralize each other, thereby enabling the surface-acoustic-wave filter 126 to behave substantially linearly and to suppress intermodulation distortion.

The second graph 600-2 depicts a third-order intermodulation distortion response of the high-quality temperature-compensated surface-acoustic-wave filter 602 of FIG. 6-1. In particular, the second graph 600-2 shows a relationship between the thickness of the softening-spring layer 128 and an amplitude of a third-order intermodulation distortion current. As shown in the graph 600-2, different thicknesses of the softening-spring layer 128 (e.g., thicknesses 604-2 and 604-3) result in portions of the third-order intermodulation distortion response being attenuated by different amounts. In general, the thicknesses of the softening-spring layer 128 and the hardening-spring layer 130 are optimized, or at least tuned, to enable the surface-acoustic-wave filter 126 to behave substantially linearly and to suppress at least a portion of the intermodulation distortion response.

In a first example, the softening-spring layer 128 has the second thickness 604-2. In this case, the surface-acoustic-wave filter 126 attenuates the third-order intermodulation distortion response by a first amount 608-1. In a second example, the softening-spring layer 128 has the third thickness 604-3. In this case, the surface-acoustic-wave filter 126 attenuates the third-order intermodulation distortion response by a second amount 608-2. As an example, a difference between the first amount 608-1 and the second amount 608-2 can be 10 dB or more (e.g., 15 dB, 20 dB, or 30 dB). In this way, the surface-acoustic-wave filter 126 suppresses intermodulation distortion. Although described with respect to the third-order intermodulation distortion, the high-quality temperature-compensated surface-acoustic-wave filter 602 can additionally or alternatively be designed to attenuate harmonic frequencies or other ordered intermodulation distortions.

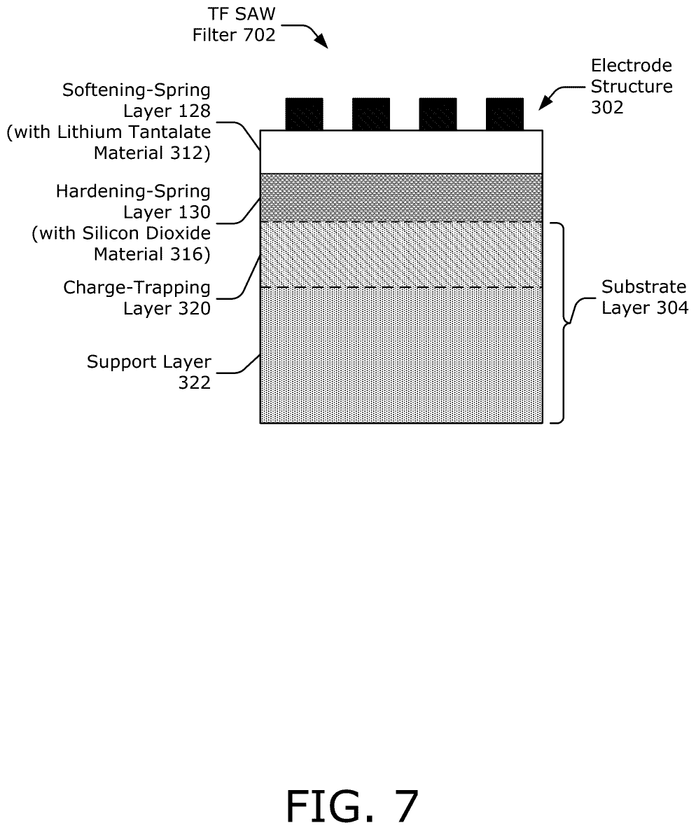

FIG. 7 illustrates an example surface-acoustic-wave filter 126 that suppresses intermodulation distortion. In this example, the surface-acoustic-wave filter 126 is implemented as a thin-film surface-acoustic-wave filter 702 (TF SAW filter 702). In the depicted configuration, the thin-film surface-acoustic-wave filter 702 includes the electrode structure 302, the softening-spring layer 128, the hardening-spring layer 130, and the substrate layer 304. The softening-spring layer 128 is implemented using the lithium tantalate material 312. The hardening-spring layer 130 is implemented using the silicon dioxide material 316. Alternatively, in other implementations not shown, the hardening-spring layer 130 can be implemented using the quartz material 314. The substrate layer 304 includes the charge-trapping layer 320 and the support layer 322. In an example implementation, the charge-trapping layer 320 includes a poly-Silicon material (e.g., a poly-crystalline silicon material), and the support layer 322 includes a silicon material.

Crystal orientations and thicknesses of the softening-spring layer 128 and the hardening-spring layer 130 of the thin-film surface-acoustic-wave filter 702 can be tailored to achieve a target electroacoustic coupling factor, a target temperature coefficient of frequency, and linear behavior that sufficiently suppresses intermodulation distortion. In general, the thickness of the softening-spring layer 128 is approximately between 400 and 600 nanometers (nm). In some cases, the thickness of the softening-spring layer 128 is approximately between 430 and 525 nm. The thickness of the hardening-spring layer 130 is approximately between 350 and 550 nm. In general, the term “approximately” can mean that any of the thicknesses can be within +/−10% of a specified value or less (e.g., within +/−5%, +/−3% or +/−2% of a specified value). In some implementations, the thickness of the softening-spring layer 128 is greater than the thickness of the hardening-spring layer 130.

An orientation of the first filter X axis 408, the second filter Y axis 410, and the third filter Z axis 412 (each of FIG. 4) relative to a crystalline structure of the lithium tantalate material 312 of the softening-spring layer 128 is defined by the Euler angles lambda (λ) 408, mu (μ) 418, and theta (θ) 426. In particular, the lithium tantalate material 312 can have a crystal orientation such that a value of the Euler angle mu (μ) 418 is approximately between −70° and −30°. In example implementations, the Euler angle mu (μ) 418 can be approximately between −48° and −60°. Alternatively, the lithium tantalate material 312 can have an equivalent crystal orientation due to crystal symmetry. In these examples, a symmetrically equivalent crystal orientation results in an Euler angle mu (μ) 418 that is approximately between 110° and 150° due to crystal symmetry. The crystal symmetry enables the lithium tantalate material 312 to have similar properties between two angles of mu (μ) 418, which are separated by 180° by, for instance, flipping the material over on the hardening-spring layer 130. A value of the Euler angles lambda (λ) 408 and theta (θ) 426 can each be approximately between −10° and +10°, approximately between −5° and +5°, or approximately equal to 0°.

An orientation of the first filter X axis 408, the second filter Y axis 410, and the third filter Z axis 412 relative to a crystalline structure of the support layer 322 is also defined by the Euler angles lambda (λ) 408, mu (μ) 418, and theta (θ) 426. In an example implementation, a crystal orientation of the support layer 322 has lambda (λ) 408 approximately equal to −45°, mu (μ) 418 approximately equal to −55°, and theta (θ) 426 approximately equal to 60°. In terms of Miller indices, this example support layer 322 can be represented as Si (1 1 1) flat [1 0 −1].

In a first example implementation, the thickness of the lithium tantalate material 312 is approximately equal to 430 nm, the thickness of the silicon dioxide material 316 is approximately equal to 400 nm, the thickness of the charge-trapping layer 320 is approximately equal to 500 nm, and the thickness of the support layer 322 is approximately equal to 600 μm. The Euler angle mu (μ) 418 is approximately equal to −48°.

In a second example implementation, the thickness of the lithium tantalate material 312 is approximately equal to 505 nm, the thickness of the silicon dioxide material 316 is approximately equal to 400 nm, the thickness of the charge-trapping layer 320 is approximately equal to 500 nm, and the thickness of the support layer 322 is approximately equal to 600 μm. The Euler angle mu (μ) 418 is approximately equal to −48°. In this case, the thickness of the lithium tantalate material 312 enables the second example implementation to attenuate intermodulation distortions by a larger amount relative to the first example implementation.

In a third example implementation, the thickness of the lithium tantalate material 312 is approximately equal to 523 nm, the thickness of the silicon dioxide material 316 is approximately equal to 400 nm, the thickness of the charge-trapping layer 320 is approximately equal to 500 nm, and the thickness of the support layer 322 is approximately equal to 600 μm. The Euler angle mu (μ) 418 is approximately equal to −60°, which enables the third example implementation to achieve a higher electroacoustic coupling factor than both the first and second example implementations.

In general, design elements of the surface-acoustic-wave filter 126 are tuned to achieve desired performance characteristics. These design elements can include the crystal orientation of the softening-spring layer 128, the thickness of the softening-spring layer 128, the crystal orientation of the hardening-spring layer 130, and the thickness of the hardening-spring layer 130, which can impact one or more performance characteristics. For example, the crystal orientation of the softening-spring layer 128 can impact the electroacoustic coupling factor. The thicknesses of the softening-spring layer 128 and the hardening-spring layer 130 can impact the electroacoustic coupling factor, the temperature coefficient of frequency, and the linear behavior of the surface-acoustic-wave filter 126 (e.g., the suppression or attenuation of the intermodulation distortion response). In some cases, the performance characteristics are further tuned with respect to each other. For example, the electroacoustic coupling factor of the surface-acoustic-wave filter 126 can be constrained in order to achieve a target temperature coefficient of frequency.

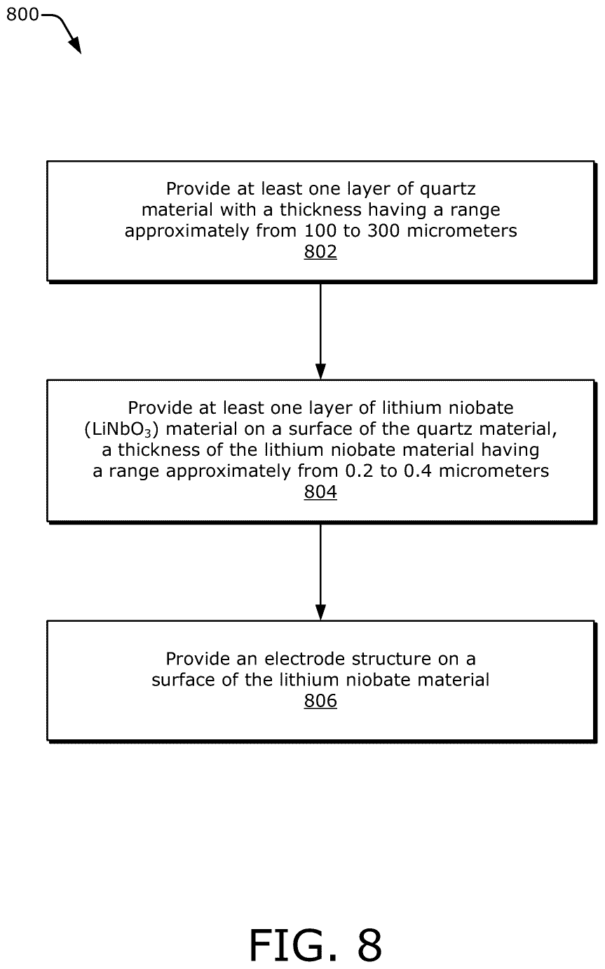

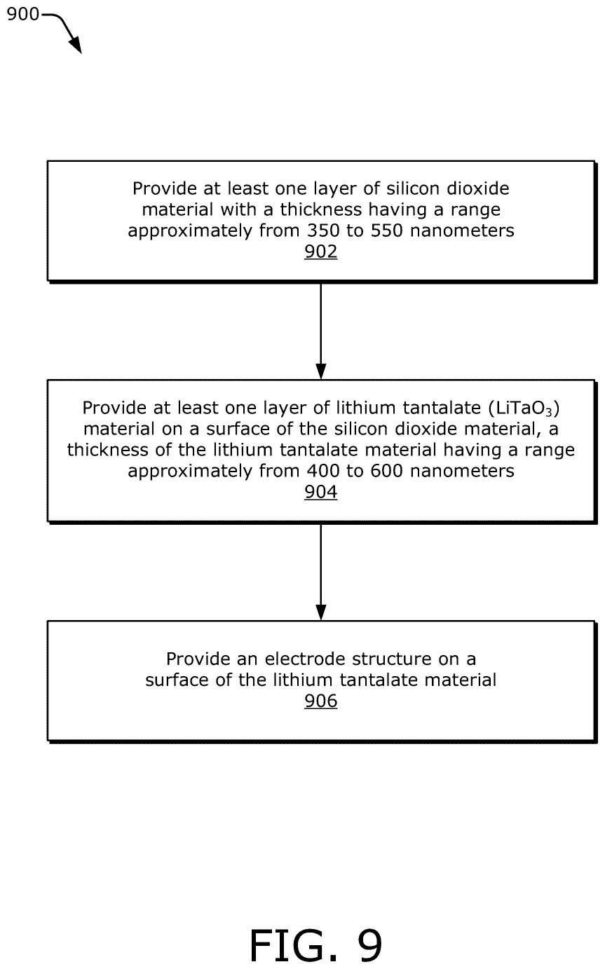

FIGS. 8 and 9 are flow diagrams illustrating example processes 800 and 900 for manufacturing a surface-acoustic-wave filter for suppressing intermodulation distortion. The process 800 is described in the form of a set of blocks 802-806 that specify operations that can be performed. The process 900 is described in the form of a set of blocks 902-906 that specify operations that can be performed. However, operations are not necessarily limited to the order shown in FIGS. 8 and 9 or described herein, for the operations may be implemented in alternative orders or in fully or partially overlapping manners. Also, more, fewer, and/or different operations may be implemented to perform the process 800, the process 900, or an alternative process. Operations represented by the illustrated blocks of the processes 800 and 900 may be performed to manufacture the surface-acoustic-wave filter 126 (e.g., of FIG. 1, 3, or 5). More specifically, the operations of the process 800 may be performed, at least in part, to create the high-quality temperature-compensated surface-acoustic-wave filter 602 of FIG. 6-1. Also, the operations of the process 900 may be performed, at least in part, to create the thin-film surface-acoustic-wave filter 702 of FIG. 7.

At block 802 in FIG. 8, at least one layer of quartz material with a thickness having a range approximately from 100 to 300 micrometers is provided. For example, a manufacturing process provides the at least one layer of quartz material 314, as shown in FIG. 6-1. The quartz material 314 has a thickness with a range approximately from 100 to 300 micrometers. The quartz material 314 represents the hardening-spring layer 130 of a surface-acoustic-wave filter 126.

At block 804, at least one layer of lithium niobate (LiNbO₃) material is provided on a surface of the quartz material. A thickness of the lithium niobate material has a range approximately from 0.2 to 0.4 micrometers. For example, the manufacturing process provides the at least one layer of lithium niobate material 310 on a surface of the quartz material 314, as shown in FIG. 6-1. The lithium niobate material 310 has a thickness with a range approximately from 0.2 to 0.4 micrometers. The lithium niobate material 310 represents the softening-spring layer 128 of the surface-acoustic-wave filter 126. In some implementations, the thickness of the lithium niobate material 310 is less than the thickness of the quartz material 314.

At block 806, an electrode structure is provided on a surface of the lithium niobate material. For example, the manufacturing process provides the electrode structure 302 on a surface of the lithium niobate material 310, as shown in FIG. 6-1.

At block 902 in FIG. 9, at least one layer of silicon dioxide material with a thickness having a range approximately from 350 to 550 nanometers is provided. For example, the manufacturing process provides the at least one layer of silicon dioxide material 316, as shown in FIG. 7. The silicon dioxide material 316 has a thickness with a range approximately from 350 to 550 nanometers. The silicon dioxide material 316 represents the hardening-spring layer 130 of a surface-acoustic-wave filter 126.

At block 904, at least one layer of lithium tantalate (LiTaO₃) material is provided on a surface of the silicon dioxide material. A thickness of the lithium tantalate material has a range approximately from 400 to 600 nanometers. For example, the manufacturing process provides the at least one layer of lithium tantalate material 312 on a surface of the silicon dioxide material 316, as shown in FIG. 7. The lithium tantalate material 312 has a thickness with a range approximately from 400 to 600 nanometers. The lithium tantalate material 312 represents the softening-spring layer 128 of the surface-acoustic-wave filter 126. In some implementations, the thickness of the lithium tantalate material 312 is greater than the thickness of the silicon dioxide material 316.

At block 906, an electrode structure is provided on a surface of the lithium tantalate material. For example, the manufacturing process provides the electrode structure 302 on a surface of the lithium niobate material 310, as shown in FIG. 7.

Some aspects are described below.

Aspect 1: An apparatus comprising:
a surface-acoustic-wave filter comprising:
   an electrode structure;
   at least one layer of quartz material with a thickness having a range approximately from 100 to 300 micrometers; and
   at least one layer of lithium niobate (LiNbO₃) material disposed between the electrode structure and the quartz material, a thickness of the lithium niobate material having a range approximately from 0.2 to 0.4 micrometers.

Aspect 2: The apparatus of aspect 1, wherein:
the thickness of the quartz material is approximately 150 micrometers; and
the thickness of the lithium niobate material is approximately 0.28 micrometers.

Aspect 3:The apparatus of aspect 1 or 2, wherein:
the lithium niobate material is configured to enable an acoustic wave to form across a planar surface of the lithium niobate material in a direction along a first filter (X) axis;
a second filter (Y) axis is along the planar surface and perpendicular to the first filter (X) axis;
a third filter (Z) axis is normal to the planar surface;
an orientation of the first filter (X) axis, the second filter (Y) axis, and the third filter (Z) axis is relative to a crystalline structure of the lithium niobate material as defined by Euler angles lambda (λ), mu (μ), and theta (θ); and
a value of the Euler angle mu (μ) has a range approximately from −36° to 28° or at least one symmetrical equivalent thereof.

Aspect 4: The apparatus of aspect 3, wherein the value of the Euler angle mu (μ) is approximately equal to 28°.

Aspect 5: The apparatus of aspect 3 or 4, wherein:
a value of the Euler angle lambda (λ) has a range approximately from −10° to 10°; and
a value of the Euler angle theta (θ) has a range approximately from −10° to 10°.

Aspect 6: The apparatus of aspect 5, wherein:
the value of the Euler angle lambda (λ) is approximately equal to 0°; and
the value of the Euler angle theta (θ) is approximately equal to 0°.

Aspect 7: The apparatus of any one of aspects 3 to 6, wherein:
an orientation of the first filter (X) axis, the second filter (Y) axis, and the third filter (Z) axis relative to a crystalline structure of the quartz material is defined by other Euler angles lambda (λ), mu (μ), and theta (θ); and
a value of the other Euler angle mu (μ) relative to the crystalline structure of the quartz material has a range approximately from −58° to −45°.

Aspect 8: The apparatus of aspect 7, wherein the value of the other Euler angle mu (μ) is approximately −56°.

Aspect 9: The apparatus of any previous aspect, wherein the surface-acoustic-wave filter is configured to have a temperature coefficient of frequency approximately equal to zero based on the thickness of the quartz material and the thickness of the lithium niobate material.

Aspect 10: The apparatus of any previous aspect, wherein:
the surface-acoustic-wave filter comprises a compensation layer; and
the electrode structure is disposed between the compensation layer and the at least one layer of lithium niobate material.

Aspect 11: The apparatus of aspect 10, wherein the compensation layer comprises silicon dioxide material.

Aspect 12: The apparatus of any previous aspect, further comprising:
a wireless transceiver coupled to at least one antenna, the wireless transceiver comprising the surface-acoustic-wave filter and configured to filter, using the surface-acoustic-wave filter, a wireless signal communicated via the at least one antenna.

Aspect 13: The apparatus of any previous aspect, wherein:
the surface-acoustic-wave filter comprises multiple cascaded resonators; and
one resonator of the multiple cascaded resonators comprises the electrode structure, the at least one layer of quartz material, and the at least one layer of lithium niobate material.

Aspect 14: The apparatus of any previous aspect, wherein the surface-acoustic-wave filter comprises a high-quality temperature-compensated surface-acoustic-wave filter.

Aspect 15: An apparatus comprising:
a surface-acoustic-wave filter configured to generate a filtered signal from a radio-frequency signal, the surface-acoustic-wave filter comprising:
   means for converting the radio-frequency signal to an acoustic wave and converting a propagated acoustic wave into the filtered signal;
   softening means for propagating the acoustic wave across a planar surface to produce the propagated acoustic wave; and
   hardening means for supporting the softening means, the softening means and the hardening means having respective thicknesses that enable the surface-acoustic-wave filter to behave substantially linearly.

Aspect 16: The apparatus of aspect 15, wherein:
the softening means is configured to have a stress-strain curve with a slope that behaves non-linearly and decreases for increasing strain; and
the hardening means is configured to have a stress-strain curve with a slope that behaves non-linearly and increases for increasing strain.

Aspect 17: The apparatus of aspect 15 or 16, wherein a thickness of the softening means is less than a thickness of the hardening means.

Aspect 18: The apparatus of aspect 17, wherein:
the thickness of the hardening means has a range approximately from 100 to 300 micrometers; and
the thickness of the softening means has a range approximately from 0.2 to 0.4 micrometers.

Aspect 19: The apparatus of any one of aspects 15 to 18, wherein the surface-acoustic-wave filter is configured to have a temperature coefficient of frequency approximately equal to zero based on the respective thicknesses of the softening means and the hardening means.

Aspect 20: A method comprising:
providing at least one layer of quartz material with a thickness having a range approximately from 100 to 300 micrometers;
providing at least one layer of lithium niobate (LiNbO₃) material on a surface of the quartz material, a thickness of the lithium niobate material having a range approximately from 0.2 to 0.4 micrometers; and
providing an electrode structure on a surface of the lithium niobate material.

Aspect 21: The method of aspect 20, wherein:
the providing of the at least one layer of quartz material comprises providing the at least one layer of quartz material with the thickness being approximately 150 micrometers; and
the providing of the at least one layer of lithium niobate material comprises providing the at least one layer of lithium niobate material with the thickness being approximately 0.28 micrometers.

Aspect 22: The method of aspect 20 or 21, further comprising:
providing a compensation layer on the surface of the lithium niobate material,
wherein the electrode structure is disposed between the compensation layer and the lithium niobate material.

Aspect 23: An apparatus comprising:
a surface-acoustic-wave filter comprising:
   an electrode structure;
   at least one hardening-spring layer; and
   at least one softening-spring layer disposed between the electrode structure and the hardening-spring layer.

Aspect 24: The apparatus of aspect 23, wherein:
the at least one softening-spring layer is configured to have a stress-strain curve with a slope that behaves non-linearly and decreases for increasing strain; and
the at least one hardening-spring layer is configured to have a stress-strain curve with a slope that behaves non-linearly and increases for increasing strain.

Aspect 25: The apparatus of aspect 23 or 24, wherein a thickness of the softening-spring layer is less than a thickness of the hardening-spring layer.

Aspect 26: The apparatus of aspect 25, wherein:
the softening-spring layer comprises lithium niobate (LiNbO₃) material; and
the hardening-spring layer comprises quartz material.

Aspect 27: The apparatus of aspect 26, wherein:
a thickness of the quartz material has a range approximately from 100 to 300 micrometers; and
a thickness of the lithium niobate material has a range approximately from 0.2 to micrometers.

Aspect 28: The apparatus of aspect 23 or 24, wherein a thickness of the softening-spring layer is greater than a thickness of the hardening-spring layer.

Aspect 29: The apparatus of aspect 28, wherein:
the softening-spring layer comprises lithium tantalate (LiTaO₃) material; and
the hardening-spring layer comprises silicon dioxide material.

Aspect 30: The apparatus of aspect 29, wherein:
a thickness of the silicon dioxide material has a range approximately from 350 to 550 nanometers; and
a thickness of the lithium tantalate material has a range approximately from 400 to 600 nanometers.

Aspect 31: An apparatus comprising:
a surface-acoustic-wave filter comprising:
   an electrode structure;
   at least one layer of quartz material; and
   at least one layer of lithium niobate (LiNbO₃) material disposed between the electrode structure and the quartz material, the lithium niobate material having a planar surface and configured to enable propagation of an acoustic wave in a direction along a first filter (X) axis, wherein:
      a second filter (Y) axis is along the planar surface and perpendicular to the first filter (X) axis;
      a third filter (Z) axis is normal to the planar surface;
      an orientation of the first filter (X) axis, the second filter (Y) axis, and the third filter (Z) axis is relative to a crystalline structure of the lithium niobate material as defined by Euler angles lambda (λ), mu (μ), and theta (θ); and
      a value of the Euler angle mu (μ) has a range approximately from −36° to 28° or at least one symmetrical equivalent thereof.

Aspect 32: The apparatus of aspect 31, wherein:
a thickness of the quartz material has a range approximately from 100 to 300 micrometers; and
a thickness of the lithium niobate material has a range approximately from 0.2 to 0.4 micrometers.

Aspect 33: An apparatus comprising:
a surface-acoustic-wave filter comprising:
   an electrode structure;
   at least one layer of silicon dioxide material with a thickness having a range approximately from 350 to 550 nanometers; and
   at least one layer of lithium tantalate (LiTaO₃) material disposed between the electrode structure and the silicon dioxide material, a thickness of the lithium tantalate material having a range approximately from 400 to 600 nanometers.

Aspect 34: The apparatus of aspect 33, wherein the thickness of the lithium tantalate material further has a range approximately from 430 to 525 nanometers.

Aspect 35: The apparatus of aspect 34, wherein:
the thickness of the silicon dioxide material is approximately 400 nanometers; and
the thickness of the lithium tantalate material is approximately 505 nanometers or approximately 523 nanometers.

Aspect 36: The apparatus of any one of aspects 33 to 35, wherein:
the lithium tantalate material is configured to enable an acoustic wave to form across a planar surface of the lithium tantalate material in a direction along a first filter (X) axis;
a second filter (Y) axis is along the planar surface and perpendicular to the first filter (X) axis;
a third filter (Z) axis is normal to the planar surface;
an orientation of the first filter (X) axis, the second filter (Y) axis, and the third filter (Z) axis is relative to a crystalline structure of the lithium tantalate material as defined by Euler angles lambda (λ), mu (μ), and theta (θ); and
a value of the Euler angle mu (μ) has a range approximately from −70° to −30° or at least one symmetrical equivalent thereof.

Aspect 37: The apparatus of aspect 36, wherein the value of the Euler angle mu (μ) is approximately equal to −60° or approximately equal to −48°.

Aspect 38: The apparatus of aspect 36 or 37, wherein:
a value of the Euler angle lambda (λ) has a range approximately from −10° to 10°; and
a value of the Euler angle theta (θ) has a range approximately from −10° to 10°.

Aspect 39: The apparatus of aspect 38, wherein:
the value of the Euler angle lambda (λ) is approximately equal to 0°; and
the value of the Euler angle theta (θ) is approximately equal to 0°.

Aspect 40: The apparatus of any one of aspects 33 to 39, wherein:
the surface-acoustic-wave filter comprises a charge-trapping layer and a support layer;
the at least one layer of silicon dioxide material is disposed between the at least one layer of lithium tantalate material and the support layer;
an orientation of the first filter (X) axis, the second filter (Y) axis, and the third filter (Z) axis relative to a crystalline structure of the support layer is defined by other Euler angles lambda (λ), mu (μ), and theta (θ);
the other lambda (λ) is approximately −45°;
the other mu (μ) is approximately −55°; and
the other theta (θ) is approximately 60°.

Aspect 41: The apparatus of any one of aspects 33 to 39, wherein:
the surface-acoustic-wave filter comprises a charge-trapping layer and a support layer;
the at least one layer of silicon dioxide material is disposed between the at least one layer of lithium tantalate material and the charge-trapping layer; and
the charge-trapping layer is disposed between the at least one layer of silicon dioxide material and the support layer.

Aspect 42: The apparatus of aspect 41, wherein:
the charge-trapping layer comprises poly-crystalline silicon material; and
the support layer comprises silicon material.

Aspect 43: The apparatus of any one of aspects 33 to 42, further comprising:
a wireless transceiver coupled to at least one antenna, the wireless transceiver comprising the surface-acoustic-wave filter and configured to filter, using the surface-acoustic-wave filter, a wireless signal communicated via the at least one antenna.

Aspect 44: The apparatus of any one of aspects 33 to 43, wherein:
the surface-acoustic-wave filter comprises multiple cascaded resonators; and
one resonator of the multiple cascaded resonators comprises the electrode structure, the at least one layer of silicon dioxide material, and the at least one layer of lithium tantalate material.

Aspect 45: The apparatus of any one of aspects 33 to 44, wherein the surface-acoustic-wave filter comprises a thin-film surface-acoustic-wave filter.

Aspect 46: A method comprising:
providing at least one layer of silicon dioxide material with a thickness having a range approximately from 350 to 550 nanometers;
providing at least one layer of lithium tantalate (LiTaO₃) material on a surface of the silicon dioxide material, a thickness of the lithium tantalate material having a range approximately from 400 to 600 nanometers; and
providing an electrode structure on a surface of the lithium tantalate material.

Aspect 47: The method of aspect 46, wherein the providing of the at least one layer of lithium tantalate material comprises providing the at least one layer of lithium tantalate material with the thickness further having a range approximately from 430 to 525 nanometers.

Aspect 48: The method of aspect 47, wherein:
the providing of the at least one layer of silicon dioxide material comprises providing the at least one layer of silicon dioxide material with the thickness being approximately 400 nanometers; and
the providing of the at least one layer of lithium tantalate material comprises providing the at least one layer of lithium tantalate material with the thickness being approximately 505 nanometers or approximately 523 nanometers.

Aspect 49: An apparatus comprising:
a surface-acoustic-wave filter comprising:
   an electrode structure;
   at least one layer of silicon dioxide material; and
   at least one layer of lithium tantalate (LiTaO₃) material disposed between the electrode structure and the silicon dioxide material, the lithium tantalate material having a planar surface and configured to enable propagation of an acoustic wave in a direction along a first filter (X) axis, wherein:
      a second filter (Y) axis is along the planar surface and perpendicular to the first filter (X) axis;
      a third filter (Z) axis is normal to the planar surface;
      an orientation of the first filter (X) axis, the second filter (Y) axis, and the third filter (Z) axis is relative to a crystalline structure of the lithium tantalate material as defined by Euler angles lambda (λ), mu (μ), and theta (θ); and
      a value of the Euler angle mu (μ) has a range approximately from −70° to −30° or at least one symmetrical equivalent thereof.

Aspect 50: The apparatus of aspect 49, wherein:
a thickness of the silicon dioxide material has a range approximately from 350 to 550 nanometers; and
a thickness of the lithium tantalate material has a range approximately from 400 to 600 nanometers.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus comprising:
a surface-acoustic-wave filter comprising:
an electrode structure;
at least one layer of quartz material with a thickness having a range approximately from 100 to 300 micrometers; and
at least one layer of lithium niobate (LiNbO₃) material disposed between the electrode structure and the quartz material, a thickness of the lithium niobate material having a range approximately from 0.2 to 0.4 micrometers.

2. The apparatus of claim 1, wherein:
the thickness of the quartz material is approximately 150 micrometers; and
the thickness of the lithium niobate material is approximately 0.28 micrometers.

3. The apparatus of claim 1, wherein:
the lithium niobate material is configured to enable an acoustic wave to form across a planar surface of the lithium niobate material in a direction along a first filter (X) axis;
a second filter (Y) axis is along the planar surface and perpendicular to the first filter (X) axis;
a third filter (Z) axis is normal to the planar surface;
an orientation of the first filter (X) axis, the second filter (Y) axis, and the third filter (Z) axis is relative to a crystalline structure of the lithium niobate material as defined by Euler angles lambda (λ), mu (μ), and theta (θ); and
a value of the Euler angle mu (μ) has a range approximately from −36° to 28° or at least one symmetrical equivalent thereof.

4. The apparatus of claim 3, wherein the value of the Euler angle mu (μ) is approximately equal to 28°.

5. The apparatus of claim 3, wherein:
a value of the Euler angle lambda (λ) has a range approximately from −10° to 10°; and
a value of the Euler angle theta (θ) has a range approximately from −10° to 10°.

6. The apparatus of claim 5, wherein:
the value of the Euler angle lambda (λ) is approximately equal to 0°; and
the value of the Euler angle theta (θ) is approximately equal to 0°.

7. The apparatus of claim 3, wherein:
an orientation of the first filter (X) axis, the second filter (Y) axis, and the third filter (Z) axis relative to a crystalline structure of the quartz material is defined by other Euler angles lambda (λ), mu (μ), and theta (θ); and
a value of the other Euler angle mu (μ) relative to the crystalline structure of the quartz material has a range approximately from −58° to −45°.

8. The apparatus of claim 7, wherein the value of the other Euler angle mu (μ) is approximately −56°.

9. The apparatus of claim 1, wherein the surface-acoustic-wave filter is configured to have a temperature coefficient of frequency approximately equal to zero based on the thickness of the quartz material and the thickness of the lithium niobate material.

10. The apparatus of claim 1, wherein:
the surface-acoustic-wave filter comprises a compensation layer; and
the electrode structure is disposed between the compensation layer and the at least one layer of lithium niobate material.

11. The apparatus of claim 10, wherein the compensation layer comprises silicon dioxide material.

12. The apparatus of claim 1, further comprising:
a wireless transceiver coupled to at least one antenna, the wireless transceiver comprising the surface-acoustic-wave filter and configured to filter, using the surface-acoustic-wave filter, a wireless signal communicated via the at least one antenna.

13. The apparatus of claim 1, wherein:
the surface-acoustic-wave filter comprises multiple cascaded resonators; and
one resonator of the multiple cascaded resonators comprises the electrode structure, the at least one layer of quartz material, and the at least one layer of lithium niobate material.

14. The apparatus of claim 1, wherein the surface-acoustic-wave filter comprises a high-quality temperature-compensated surface-acoustic-wave filter.

15. An apparatus comprising:
a surface-acoustic-wave filter configured to generate a filtered signal from a radio-frequency signal, the surface-acoustic-wave filter comprising:
means for converting the radio-frequency signal to an acoustic wave and converting a propagated acoustic wave into the filtered signal;
softening means for propagating the acoustic wave across a planar surface to produce the propagated acoustic wave; and
hardening means for supporting the softening means, the softening means and the hardening means having respective thicknesses that enable the surface-acoustic-wave filter to behave substantially linearly.

16. The apparatus of claim 15, wherein:
the softening means is configured to have a stress-strain curve with a slope that behaves non-linearly and decreases for increasing strain; and
the hardening means is configured to have a stress-strain curve with a slope that behaves non-linearly and increases for increasing strain.

17. The apparatus of claim 15, wherein a thickness of the softening means is less than a thickness of the hardening means.

18. The apparatus of claim 17, wherein:
the thickness of the hardening means has a range approximately from 100 to 300 micrometers; and
the thickness of the softening means has a range approximately from 0.2 to 0.4 micrometers.

19. The apparatus of claim 15, wherein the surface-acoustic-wave filter is configured to have a temperature coefficient of frequency approximately equal to zero based on the respective thicknesses of the softening means and the hardening means.

20. A method comprising:
providing at least one layer of quartz material with a thickness having a range approximately from 100 to 300 micrometers;
providing at least one layer of lithium niobate (LiNbO₃) material on a surface of the quartz material, a thickness of the lithium niobate material having a range approximately from 0.2 to 0.4 micrometers; and
providing an electrode structure on a surface of the lithium niobate material.

21. The method of claim 20, wherein:
the providing of the at least one layer of quartz material comprises providing the at least one layer of quartz material with the thickness being approximately 150 micrometers; and
the providing of the at least one layer of lithium niobate material comprises providing the at least one layer of lithium niobate material with the thickness being approximately 0.28 micrometers.

22. The method of claim 20, further comprising:
providing a compensation layer on the surface of the lithium niobate material,
wherein the electrode structure is disposed between the compensation layer and the lithium niobate material.

23. An apparatus comprising:
a surface-acoustic-wave filter comprising:
an electrode structure;
at least one hardening-spring layer; and
at least one softening-spring layer disposed between the electrode structure and the hardening-spring layer.

24. The apparatus of claim 23, wherein:
the at least one softening-spring layer is configured to have a stress-strain curve with a slope that behaves non-linearly and decreases for increasing strain; and
the at least one hardening-spring layer is configured to have a stress-strain curve with a slope that behaves non-linearly and increases for increasing strain.

25. The apparatus of claim 23, wherein a thickness of the softening-spring layer is less than a thickness of the hardening-spring layer.

26. The apparatus of claim 25, wherein:
the softening-spring layer comprises lithium niobate (LiNbO₃) material; and
the hardening-spring layer comprises quartz material.

27. The apparatus of claim 26, wherein:
a thickness of the quartz material has a range approximately from 100 to 300 micrometers; and
a thickness of the lithium niobate material has a range approximately from 0.2 to micrometers.

28. The apparatus of claim 23, wherein a thickness of the softening-spring layer is greater than a thickness of the hardening-spring layer.

29. The apparatus of claim 28, wherein:
the softening-spring layer comprises lithium tantalate (LiTaO₃) material; and
the hardening-spring layer comprises silicon dioxide material.

30. The apparatus of claim 29, wherein:
a thickness of the silicon dioxide material has a range approximately from 350 to 550 nanometers; and
a thickness of the lithium tantalate material has a range approximately from 400 to 600 nanometers.
